(19) United States
(12) Patent Application Publication
(10) Pub. No.: US 2026/0082715 A1
(43) Pub. Date: Mar. 19, 2026

(54) IMAGING ELEMENT AND ELECTRONIC APPARATUS

(71) Applicant: SONY SEMICONDUCTOR SOLUTIONS CORPORATION, Kanagawa (JP)

(72) Inventors: Tomohiko KAWAMURA, Kanagawa (JP); Tetsuya UCHIDA, Kanagawa (JP)

(73) Assignee: SONY SEMICONDUCTOR SOLUTIONS CORPORATION, Kanagawa (JP)

(21) Appl. No.: 19/108,824

(22) PCT Filed: Aug. 16, 2023
(86) PCT No.: PCT/JP2023/029557

§ 371 Date: Mar. 5, 2025

(30) Foreign Application Priority Data
Sep. 15, 2022 (JP) 2022-147341

(51) Int. Cl. H10F 39/00; H10F 39/18

(52) U.S. Cl. CPC H10F 39/807; H10F 39/182; H10F 39/802; H10F 39/8037

(57) ABSTRACT

An imaging element of an embodiment of the present disclosure includes: a semiconductor substrate including a photoelectric converter for each pixel; one or more pixel transistors provided in one surface of the semiconductor substrate; and a first element isolation section and a second element isolation section having different depths from each other that are embedded in the one surface of the semiconductor substrate and define an active region of the one or more pixel transistors, in which a portion of a gate electrode of the one or more pixel transistors is embedded in at least one of the first and second element isolation sections at different depths.

### TECHNICAL FIELD

The present disclosure relates to an imaging element and an electronic apparatus.

### BACKGROUND ART

For example, PTL 1 discloses a solid-state imaging element intended to improve the area efficiency in such a way that, in a side surface of, of an isolation section having an STI and an isolation section having a DTI that define an active region of a pixel transistor, the isolation section having the DTI, semiconductor regions having different impurity concentration from each other are formed in a depth direction of the isolation section.

### CITATION LIST

### Patent Literature

PTL 1: Japanese Unexamined Patent Application Publication No. 2020-13817

### SUMMARY OF INVENTION

Incidentally, improvement of image quality is expected of an imaging element.

It is desirable to provide an imaging element and an electronic apparatus that make it possible to improve the image quality.

An imaging element of an embodiment of the present disclosure includes: a semiconductor substrate including a photoelectric converter for each pixel; one or more pixel transistors provided in one surface of the semiconductor substrate; and first and second element isolation sections having different depths from each other that are embedded in the one surface of the semiconductor substrate and define an active region of the one or more pixel transistors, in which a portion of a gate electrode of the one or more pixel transistors is embedded in at least one of the first and second element isolation sections at different depths.

An electronic apparatus of an embodiment of the present disclosure includes the imaging element of the embodiment of the present disclosure.

In the imaging element and the electronic apparatus of the embodiments of the present disclosure, a portion of a gate electrode of the one or more pixel transistors is embedded at different depths in at least one of the first and second element isolation sections provided at the semiconductor substrate and define the active region of the one or more pixel transistors. Thereby, the shape of a channel region formed below the gate electrode is controlled.

### BRIEF DESCRIPTION OF DRAWINGS

FIG. 1 is a schematic cross-sectional view illustrating a configuration of a main part of an imaging element according to a first embodiment of the present disclosure.

FIG. 2 is a schematic plan view of the imaging element illustrated in FIG. 1.

FIG. 3 is a block diagram illustrating an entire configuration of an imaging device including the imaging element illustrated in FIG. 1.

FIG. 4 is an equivalent circuit diagram of each unit pixel of the imaging device illustrated in FIG. 3.

FIG. 5A is a schematic cross-sectional view that describes an example of a process of manufacturing the imaging element illustrated in FIG. 1.

FIG. 5B is a schematic cross-sectional view illustrating a process subsequent to FIG. 5A.

FIG. 5C is a schematic cross-sectional view illustrating a process subsequent to FIG. 5B.

FIG. 5D is a schematic cross-sectional view illustrating a process subsequent to FIG. 5C.

FIG. 6 is a schematic cross-sectional view illustrating a configuration of a main part of an imaging element according to modification example 1 of the present disclosure.

FIG. 7 is a schematic cross-sectional view illustrating a configuration of a main part of an imaging element according to modification example 2 of the present disclosure.

FIG. 8 is a schematic plan view of the imaging element illustrated in FIG. 7.

FIG. 9 is a schematic cross-sectional view of an FD conversion gain switching transistor illustrated in FIG. 8.

FIG. 10 is a diagram illustrating a potential under the gate electrode of the imaging element illustrated in FIG. 7.

FIG. 11 is a schematic cross-sectional view illustrating an example of a configuration of a main part of an imaging element according to a second embodiment of the present disclosure.

FIG. 12 is a schematic plan view of the imaging element illustrated in FIG. 11.

FIG. 13 is a schematic cross-sectional view illustrating a configuration of a main part of an imaging element according to modification example 3 of the present disclosure.

FIG. 14 is a schematic cross-sectional view illustrating a configuration of a main part of an imaging element according to modification example 4 of the present disclosure.

FIG. 16 is a diagram illustrating a potential under the gate electrode of the imaging element illustrated in FIG. 14.

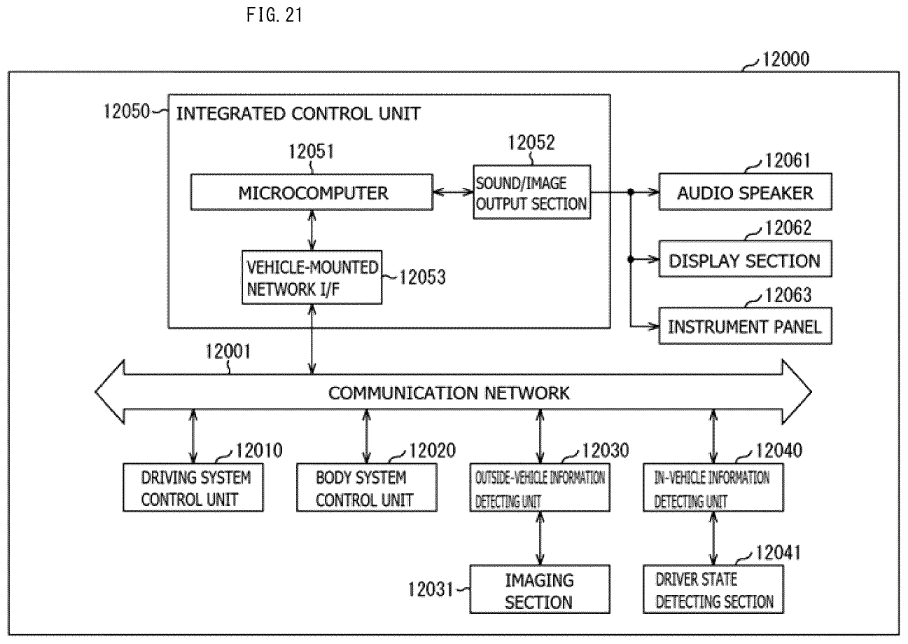

FIG. 15 is a schematic plan view of the imaging element illustrated in FIG. 14.

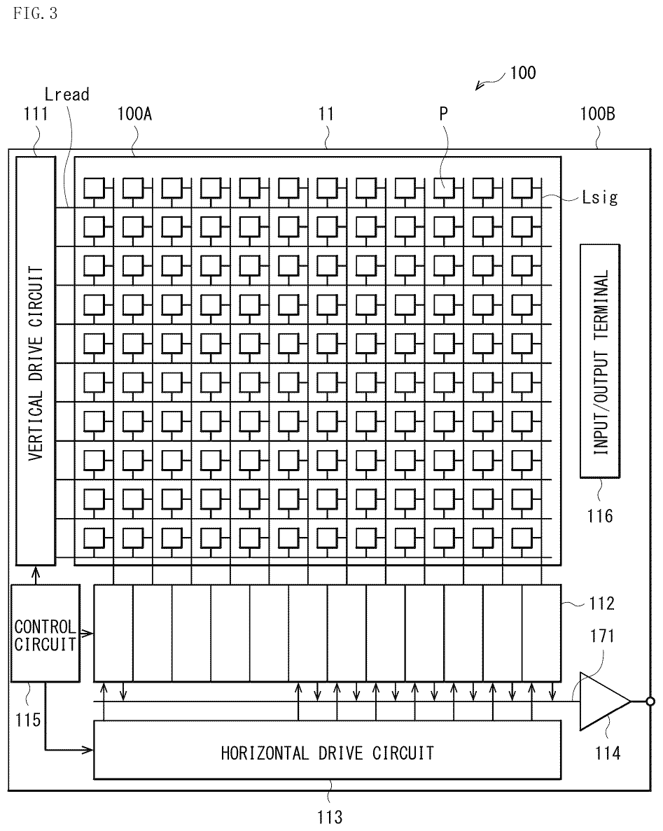

FIG. 17 is a block diagram illustrating an example of a configuration of an electronic apparatus using the imaging device illustrated in FIG. 3.

FIG. 18A is a schematic diagram illustrating an example of an entire configuration of a light detection system using the imaging device illustrated in FIG. 3.

FIG. 18B is a diagram illustrating an example of a circuit configuration of the light detection system illustrated in FIG. 18A.

FIG. 19 is a view depicting an example of a schematic configuration of an endoscopic surgery system.

FIG. 20 is a block diagram depicting an example of a functional configuration of a camera head and a camera control unit (CCU).

FIG. 21 is a block diagram depicting an example of schematic configuration of a vehicle control system.

FIG. 22 is a diagram of assistance in explaining an example of installation positions of an outside-vehicle information detecting section and an imaging section.

### MODES FOR CARRYING OUT THE INVENTION

With reference to the drawings, embodiments of the present disclosure will be described in detail below. The following description is a specific example of the present disclosure, and the present disclosure is not limited to the following aspects. Furthermore, as for the layout, dimensions, dimensional ratio, etc. of each component illustrated in each drawing, the present disclosure is not limited to those. It is to be noted that the order of description is as follows.

### 1. First Embodiment

(An example of an imaging element in which a portion of a gate electrode is embedded in an STI)

### 2. Modification Example 1

(An example of an imaging element in which both of the STI and an FTI are embedded with a portion of the gate electrode to cause the STI-side portion to be embedded deeper)

### 3. Modification Example 2

(An example where a highly concentrated impurity diffusion layer is provided on a side surface the FTI)

### 4. Second Embodiment

(An example of an imaging element in which a portion of the gate electrode is embedded in the FTI)

### 5. Modification Example 3

(An example of an imaging element in which both of the STI and the FTI are embedded with a portion of the gate electrode to cause the FTI-side portion to be embedded deeper)

### 6. Modification Example 4

(An example where a highly concentrated impurity diffusion layer is provided in the lower part of the STI)

### 7. Application Examples

### 8. Practical Application Examples

### 1. First Embodiment

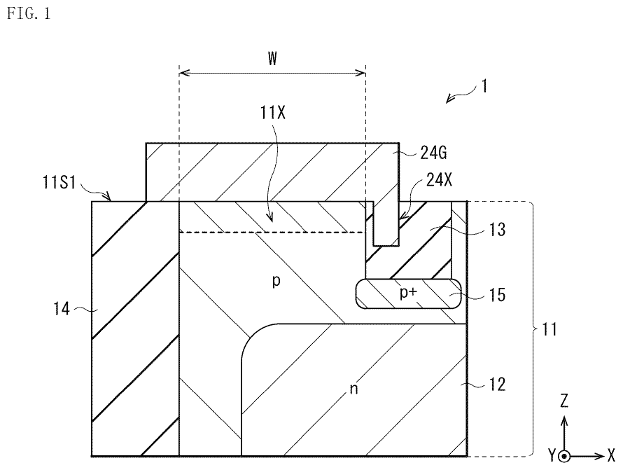

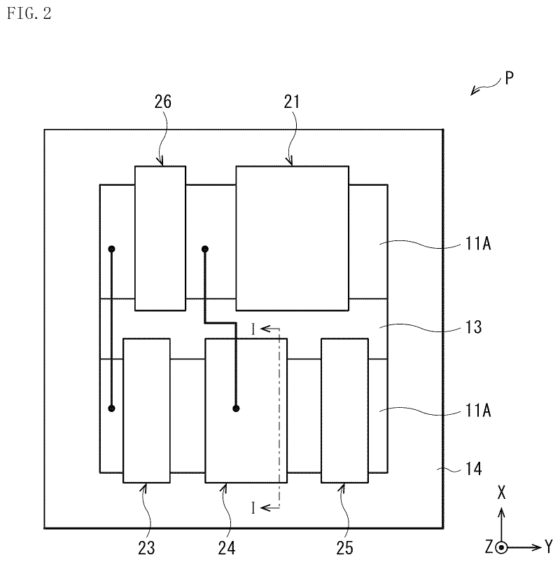

FIG. 1 schematically illustrates a cross-sectional configuration of a main part of an imaging element (an imaging element 1) according to a first embodiment of the present disclosure. FIG. 2 schematically illustrates a planar configuration of the imaging element 1 illustrated in FIG. 1, and FIG. 1 illustrates a cross-section along a line I-I illustrated in FIG. 2. For example, the imaging element 1 constitutes one pixel (a unit pixel P) in an imaging device (an imaging device 100, see FIG. 3) such as a complementary metal-oxide semiconductor (CMOS) image sensor used in an electronic apparatus such as a digital still camera or a video camera.

### [Entire Configuration of Imaging Device]

FIG. 3 illustrates an entire configuration of an imaging device (the imaging device 100) according to an embodiment of the present disclosure.

For example, the imaging device 100 takes in incident light (image light) from a subject through an optical lens system (not illustrated), and converts an amount of incident light formed as an image on an imaging plane into an electrical signal on a pixel-by-pixel basis and outputs the electrical signal as a pixel signal. The imaging device 100 includes, on a semiconductor substrate 11, a pixel section 100A as an imaging area, and, in a region around this pixel section 100A, for example, a vertical drive circuit 111, a column signal processing circuit 112, a horizontal drive circuit 113, an output circuit 114, a control circuit 115, and an input/output terminal 116.

The pixel section 100A includes, for example, a plurality of unit pixels P two-dimensionally arranged in a matrix. These unit pixels P are provided with, for example, a pixel drive line Lread (specifically, a row selection line and a reset control line) for each pixel row and a vertical signal line Lsig for each pixel column. The pixel drive line Lread is for transmitting a drive signal for readout of a signal from a unit pixel P. One end of the pixel drive line Lread is coupled to an output terminal of the vertical drive circuit 111 corresponding to each row.

The vertical drive circuit 111 is a pixel drive unit that includes a shift register, an address decoder, etc., and drives each unit pixel P in the pixel section 100A, for example, on a row-by-row basis. A signal output from each of unit pixels P of a pixel row selected and scanned by the vertical drive circuit 111 is supplied to the column signal processing circuit 112 through a vertical signal line Lsig. The column signal processing circuit 112 includes an amplifier, a horizontal selection switch, etc. provided for each vertical signal line Lsig.

The horizontal drive circuit 113 includes a shift register, an address decoder, etc., and drives each horizontal selection switch of the column signal processing circuit 112 in turn while scanning. By this selective scanning by the horizontal drive circuit 113, a signal of each pixel transmitted through a respective vertical signal line Lsig is output to a horizontal signal line 117 in turn, and is transmitted to the outside of the semiconductor substrate 11 through the horizontal signal line 117.

The output circuit 114 performs signal processing on signals sequentially supplied from each of the column signal processing circuits 112 through the horizontal signal line 117 and outputs the processed signals. For example, the output circuit 114 performs only buffering in some cases, and performs black level adjustment, column variation correction, a variety of digital signal processing, etc. in other cases.

A circuit part including the vertical drive circuit 111, the column signal processing circuit 112, the horizontal drive circuit 113, the horizontal signal line 117, and the output circuit 114 may be formed directly on the semiconductor substrate 11, or may be provided in an external control IC. Furthermore, the circuit part may be formed on another substrate coupled by cable or something.

The control circuit 115 receives a clock given from the outside of the semiconductor substrate 11, data that orders an operation mode, etc., and outputs data such as internal information of the imaging device 100. Furthermore, the control circuit 115 includes a timing generator that generates various timing signals, and performs control of driving the peripheral circuits such as the vertical drive circuit 111, the column signal processing circuit 112, and the horizontal drive circuit 113 on the basis of various timing signals generated by the timing generator.

The input/output terminal 116 exchanges a signal with the outside.

### [Circuit Configuration of Imaging Element (Unit Pixel)]

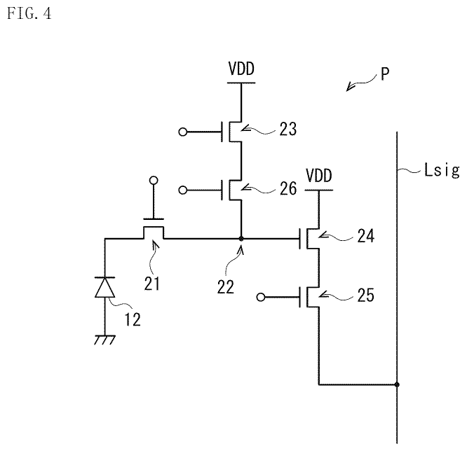

FIG. 4 illustrates an example of an equivalent circuit (a pixel circuit) of a unit pixel P. The unit pixel P is provided with multiple transistors. To drive these multiple transistors, multiple pixel drive lines Lread are coupled to one unit pixel P. The unit pixel P is coupled to a vertical signal line Lsig.

The unit pixel P includes, for example, a photoelectric converter 12 including a photodiode (PD), a transfer transistor (TRG) 21, and a floating diffusion (FD) 22 electrically coupled to the TRG 21. In the photoelectric converter 12, a cathode is electrically coupled to a source of the TRG 21, and an anode is electrically coupled to a reference potential line (for example, the ground).

The photoelectric converter 12 photoelectrically converts light that has entered and generate an electric charge according to an amount of the received light. The TRG 21 is, for example, an n-type complementary metal-oxide semiconductor (CMOS) transistor. In the TRG 21, a drain is electrically coupled to the FD 22, and a gate is coupled to a pixel drive line Lread. This pixel drive line Lread is a part of the multiple pixel drive lines Lread coupled to one unit pixel P. The TRG 21 transfers the electric charge generated by the photoelectric converter 12 to the FD 22. The FD 22 is, for example, an n-type diffusion layer formed within a p-well of the semiconductor substrate 11. The FD 22 is a charge holding means that temporarily holds the electric charge transferred from the photoelectric converter 12, and is a charge-voltage conversion means that generates a voltage according to an amount of the electric charge.

The pixel circuit includes, for example, four transistors, specifically, a reset transistor (RST) 23, an amplifier transistor (AMP) 24, a selection transistor (SEL) 25, and an FD conversion gain switching transistor (FDG) 26.

The FD 22 is electrically coupled to a gate of the AMP 24 and a source of the FDG 26. A drain of the FDG 26 is coupled to a source of the RST 23, and a gate of the FDG 26 is coupled to a pixel drive line Lread. This pixel drive line Lread is a part of the multiple pixel drive lines Lread coupled to one unit pixel P. A drain of the RST 23 is coupled to a power line VDD, and a gate of the RST is coupled to a pixel drive line Lread. This pixel drive line Lread is a part of the multiple pixel drive lines Lread coupled to one unit pixel P. The gate of the AMP 24 is coupled to the FD 22, a source of the AMP 24 is coupled to a drain of the SEL 25, and a drain of the AMP 24 is coupled to the power line VDD. A source of the SEL 25 is coupled to the vertical signal line Lsig, and a gate of the SEL 25 is coupled to a pixel drive line Lread. This pixel drive line Lread is a part of the multiple pixel drive lines Lread coupled to one unit pixel P.

If the TRG 21 goes into an on-state, the TRG 21 transfers an electric charge in the photoelectric converter 12 to the FD 22. The gate (a transfer gate) of the TRG 21 includes, for example, a so-called vertical electrode, and extends, for example, from a front surface (a surface 11S1) of the semiconductor substrate 11 to a depth that reaches the photoelectric converter 12. The RST 23 resets the potential of the FD 22 to a predetermined potential. If the RST 23 goes into an on-state, the RST 23 resets the potential of the FD 22 to the potential of the power line VDD. The SEL 25 controls the timing to output a pixel signal from the pixel circuit. The AMP 24 generates, as a pixel signal, a signal of a voltage according to the level of an electric charge held in the FD 22. The AMP 24 is coupled to the vertical signal line Lsig through the SEL 25. The AMP 24 constitutes a source follower in the column signal processing circuit 112. If the SEL 25 goes into an on-state, the AMP 24 outputs the voltage of the FD 22 to the column signal processing circuit 112 through the vertical signal line Lsig. The RST 23, the AMP 24, and the SEL 25 are, for example, an n-type CMOS transistor.

The FDG 26 is used when the gain of charge-voltage conversion in the FD 22 is changed. In general, a pixel signal is small when an image is taken in a dark place. On the basis of Q=CV, when charge-voltage conversion is performed, if the capacitance of the FD 22 (the FD capacitance C) is high, V, a voltage converted in the AMP 24, becomes low. Meanwhile, a pixel signal becomes large in a bright place; therefore, if the FD capacitance C is not high, the FD 22 fails to receive an electric charge of the photoelectric converter 12. Furthermore, the FD capacitance C has to be high to cause V, a voltage converted in the AMP 24, not to be too high (i.e., to be low). In light of these, when the FDG 26 has been turned ON, the gate capacitance increases by that of the FDG 26, thus the entire FD capacitance C becomes high. Meanwhile, when the FDG 26 has been turned OFF, the entire FD capacitance C becomes low. In this way, by switching the FDG 26 ON and OFF, it becomes possible for the FD capacitance C to be variable and possible to switch the conversion efficiency. The FDG 26 is, for example, an n-type CMOS transistor.

It is to be noted that a configuration with no FDG 26 provided is also possible. At this time, for example, the pixel circuit includes, for example, three transistors: the RST 23, the AMP 24, and the SEL 25. The pixel circuit includes, for example, at least one transistor out of the RST 23, the AMP 24, the SEL 25, and the FDG 26.

Furthermore, the SEL 25 may be provided between the power line VDD and the AMP 24. In this case, the drain of the RST 23 is electrically coupled to the power line VDD and the drain of the SEL 25. The source of the SEL 25 is electrically coupled to the drain of the AMP 24, and the gate of the SEL 25 is electrically coupled to a pixel drive line Lread. The source of the AMP 24 (an output terminal of the pixel circuit) is electrically coupled to the vertical signal line Lsig, and the gate of the AMP 24 is electrically coupled to the source of the RST 23.

Hereinafter, the RST 23, the AMP 24, the SEL 25, and the FDG 26 are referred to as a pixel transistor.

### [Configuration of Imaging Element]

As described above, the imaging element 1 constituting a unit pixel P includes the photoelectric converter 12, the TRG 21, and the FD 22, and further includes, as pixel transistors, the RST 23, the AMP 24, the SEL 25, and the FDG 26. As illustrated in FIG. 1, the photoelectric converter 12 is formed to be embedded in the semiconductor substrate 11, and the FD 22, the RST 23, the AMP 24, the SEL 25, and the FDG 26 are provided on the side of the front surface (the surface 11S1) of the semiconductor substrate 11. It is to be noted that although not illustrated, on a surface (a back surface) on the side opposite to the front surface (the surface 11S1) of the semiconductor substrate 11, a color filter and an on-chip lens are disposed. The imaging element 1 is a so-called back-illuminated imaging element that uses this back surface of the semiconductor substrate 11 as a light receiving surface, and, on the side of the front surface (the surface 11S1), is provided with a wiring layer that drives the pixel transistors provided, for example, for each unit pixel P.

It is to be noted that symbols “p” and “n” in the drawings denote a p-type semiconductor region and an n-type semiconductor region, respectively. Furthermore, a trailing “+(plus)” sign after “p” and “n” denotes that the p-type or n-type impurity concentration is higher than that of a surrounding p-type or n-type semiconductor region. Much the same is true for the subsequent drawings.

The semiconductor substrate 11 includes, for example, a silicon (Si) substrate. The semiconductor substrate 11 has a p-type semiconductor region (p) (a p-well) adjacent to the front surface (the surface 11S1), and is provided with an n-type semiconductor region (n) constituting a photodiode in a predetermined region.

The photoelectric converter 12 includes, for example, a positive-intrinsic-negative (PIN) photodiode, and, as described above, has a p-n junction, for example, for each unit pixel P.

The semiconductor substrate 11 is provided with element isolation sections 13 and 14. The element isolation section 13 corresponds to a specific example of a “first element isolation section” of the present disclosure, and, for example, electrically isolates each pixel transistor provided in a unit pixel P. The element isolation section 13 has, for example, a shallow trench isolation (STI) structure. The element isolation section 14 corresponds to a specific example of a “second element isolation section” of the present disclosure, and electrically isolates between adjacent unit pixels P. The element isolation section 14 is formed to be deeper in a thickness direction of the semiconductor substrate 11 (a Z-axis direction) than that is in the element isolation section 13, and has, for example, a full trench isolation (FTI) structure in which a trench goes through the semiconductor substrate 11 between the front surface (the surface 11S1) and the back surface of the semiconductor substrate 11.

The element isolation sections 13 and 14 define an active region 11A of multiple pixel transistors (the RST 23, the AMP 24, the SEL 25, and the FDG 26) provided in the unit pixel P. The active region 11A of the pixel transistors here is, for example, as illustrated in FIG. 2, a region in which a gate electrode and a source/drain that constitute a pixel transistor are formed. Specifically, it has a configuration in which a channel region formed between the source and the drain of a pixel transistor under the gate electrode of the pixel transistor (for example, as illustrated in FIG. 1, a length of a channel region 11X formed under a gate electrode 24G of the AMP 24 (a channel length (W)) is defined by the element isolation section 13 and the element isolation section 14.

In the pixel section 100A, the element isolation sections 14 are provided, for example, in a grid pattern to isolate the unit pixels P adjacent in a row direction and a column direction. Within a unit pixel P, the element isolation section 13 is provided between the RST 23, the AMP 24, and the SEL 25 and the TRG 21 and the FDG 26 that are provided in parallel in, for example, a Y-axis direction. The element isolation sections 13 and 14 formed, for example, using a material such as silicon oxide (SiOₓ).

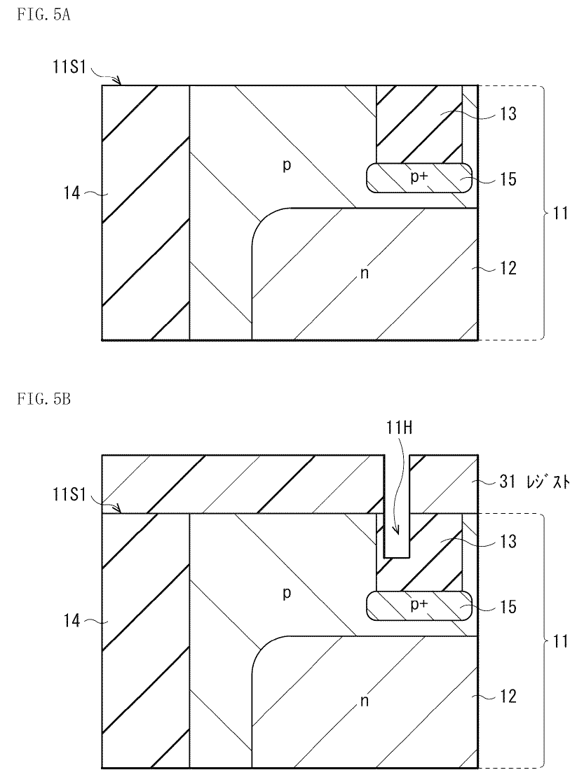

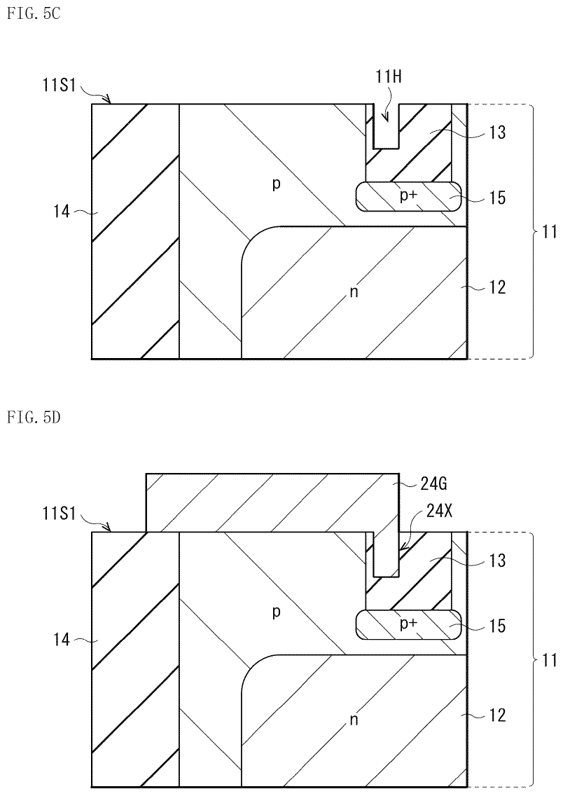

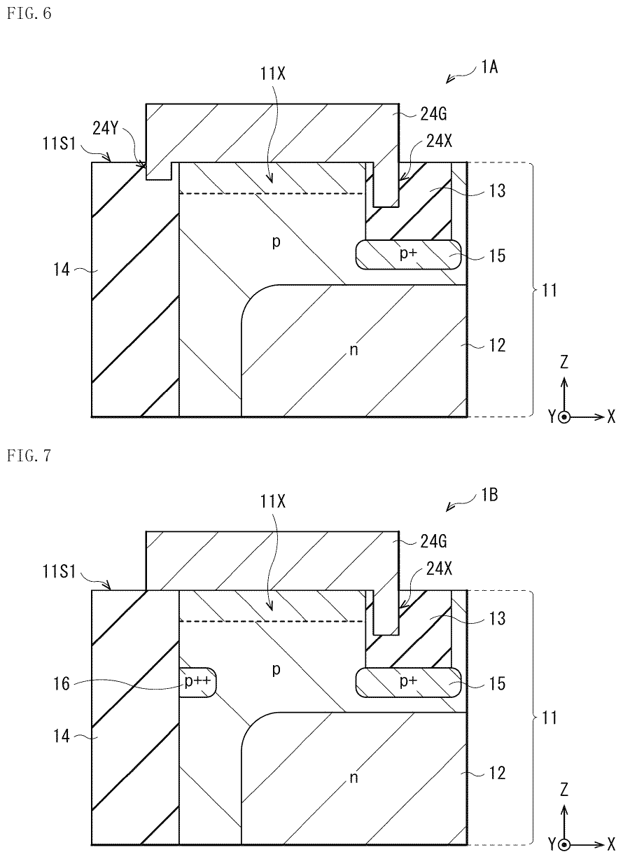

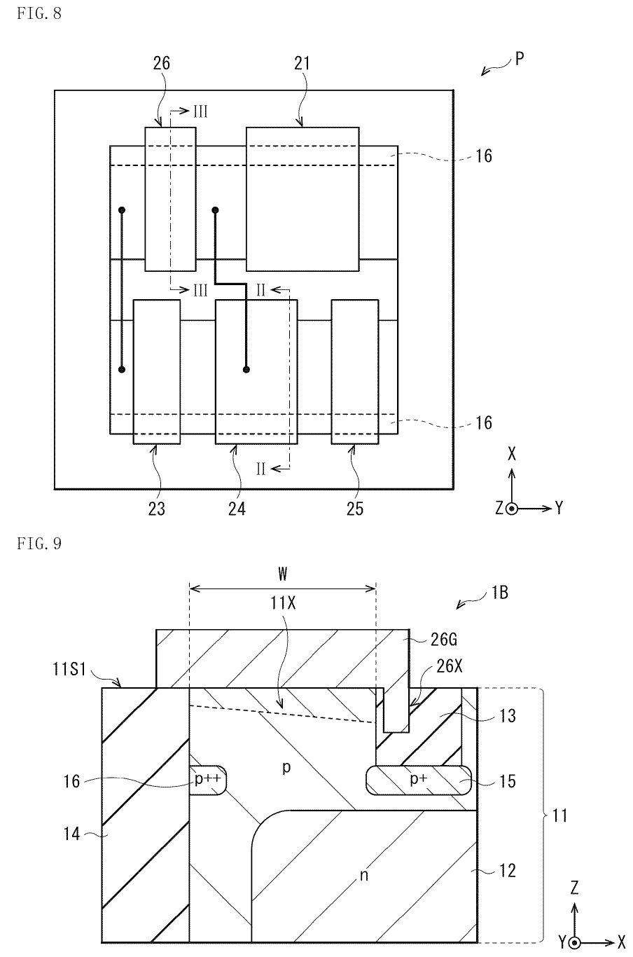

Below the element isolation section 13, a p-type diffusion layer (p+) 15 is provided. The p-type diffusion layer (p+) 15 corresponds to a specific example of a “first impurity diffusion layer” of the present disclosure. The p-type diffusion layer (p+) 15 is for suppressing dark current due to a defect caused when a trench (an opening 11H, for example, see FIG. 5B) included in the element isolation section 13 is formed.

In the present embodiment, a portion of the gate electrode of all or some of the multiple pixel transistors (the RST 23, the AMP 24, the SEL 25, and the FDG 26) included in the pixel circuit is embedded in the element isolation section 13. Thus, when each pixel transistor has gone into the ON state, it becomes possible to suppress the depth of the channel region 11X formed in the active region 11A under the gate electrode. Specifically, as illustrated in FIG. 1, by embedding, for example, a portion (an embedded part 24X) of the gate electrode 24G of the AMP 24, generally, it becomes possible for the channel region 11X formed deep on the side of the element isolation section 14 due to a difference in depth and a bias in impurity concentration between the element isolation sections 13 and 14 to be formed deep on the side of the element isolation section 13 as well. That is, the channel region 11X formed in the active region 11A under the gate electrode 24G is formed between the element isolation section 13 and the element isolation section 14 with a substantially uniform depth.

### [Method for Manufacturing Imaging Element]

The gate electrode (for example, the gate electrode 24G) of the imaging element 1 of the present embodiment is able to be formed, for example, as follows.

First, as illustrated in FIG. 5A, the element isolation sections 13 and 14 are formed and the n-type semiconductor region (n) that serves as the photoelectric converter 12 and the p-type diffusion layer (p+) 15 are formed in the semiconductor substrate 11 through ion implantation. Then, as illustrated in FIG. 5B, a resist 31 is patterned on the front surface (the surface 11S1) of the semiconductor substrate 11 by photolithography and etching, and the opening 11H is formed in the element isolation section 13.

Next, as illustrated in FIG. 5C, after the resist 31 is removed, although not illustrated, an insulating film is formed over the front surface (the surface 11S1) of the semiconductor substrate 11 and a side surface and a bottom surface of the opening 11H, and a gate insulating film of each pixel transistor is formed. Then, after a conductive film is formed using a sputtering technique, the conductive film is processed by photolithography and etching. Thus, as illustrated in FIG. 5D, the gate electrode with a portion thereof embedded in the element isolation section 13 (for example, the gate electrode 24G having the embedded part 24X) is formed.

[operation of Imaging Element]

In the imaging element 1, for example, as a unit pixel P of the imaging device 100, a signal charge (for example, an electron) is acquired as follows. If light enters the imaging element 1 through the on-chip lens, the light passes through the color filter, etc., and is detected (absorbed) by the photoelectric converter 12 provided for each unit pixel P, and light of a predetermined wavelength is photoelectrically converted. Of an electron-hole pair generated in the photoelectric converter 12, for example, the electron is moved to and accumulated in the n-type semiconductor region (+), and the hole is discharged from the power line VDD.

### [Actions and Effects]

In the imaging element 1 of the present embodiment, of the element isolation sections 13 and 14 provided in the semiconductor substrate 11 and having different depths from each other that define the active region 11A of the multiple pixel transistors constituting the pixel circuit, a portion of the gate electrode (for example, the gate electrode 24G of the AMP 24) of the pixel transistor is embedded in the isolation section 13 having the STI structure. Thus, the shape of the channel region 11X formed below the gate electrode is controlled. A description about this is provided below.

In a case where element isolation sections that define an active region of multiple pixel transistors constituting a pixel circuit are provided to have different depths such as an STI structure and an FTI structure as described above, due to their difference in depth and a bias in impurity concentration caused by a p-type diffusion region for dark current prevention formed directly beneath an STI, a channel is formed deep on the side of an FTI. This bias in the depth of the channel increases a characteristic variation of the pixel transistors. In particular, a characteristic variation of amplifier transistors causes, in an image sensor, degradation of the image quality. Furthermore, current is likely to flow to a side wall interface of the FTI, thereby an electrical charge trapped in an FTI interface having more defects than an interface with a gate oxide film is increased, which leads to worsening of random telegraph signal (RTS) noise.

Meanwhile, in the present embodiment, a portion (the embedded part 24X) of the gate electrode of multiple pixel transistors constituting the pixel circuit (for example, the gate electrode 24G of the AMP 24) embedded in the element isolation section 13 having the STI structure. Thus, the channel region 11X formed below the gate electrode is able to be formed deep on the side of the element isolation section 13 as well, and the channel region 11X having a substantially uniform depth is formed between the element isolation section 13 and the element isolation section 14.

As above, in the imaging element 1 and the imaging device 100 of the present embodiment, the characteristic variation of the pixel transistors is improved, and the RTS noise is reduced, and therefore it is possible to improve the image quality.

A second embodiment of the present disclosure and modification examples 1 to 4 are described below. It is to be noted that the same component as the above-described first embodiment is assigned the same reference numeral, and its description is omitted accordingly.

### 2. Modification Example 1

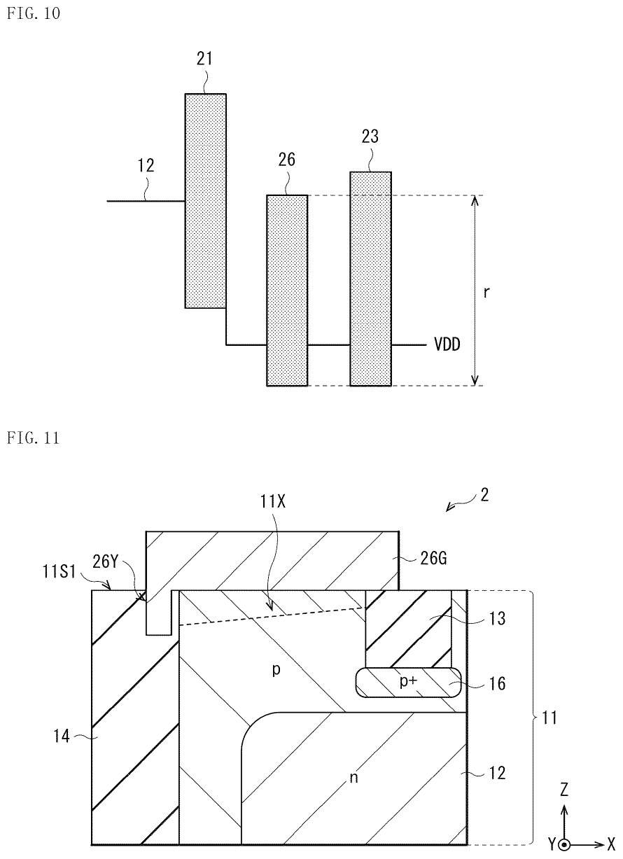

FIG. 6 schematically illustrates a cross-sectional configuration of a main part of an imaging element (an imaging element 1A) according to modification example 1 of the present disclosure. For example, as in the above-described first embodiment, the imaging element 1A constitutes one pixel (a unit pixel P) in the imaging device 100 such as a CMOS image sensor used in an electronic apparatus such as a digital still camera or a video camera.

In the above-described first embodiment, a portion (the embedded part 24X) of the gate electrode of the multiple pixel transistors (for example, the gate electrode 24G of the AMP 24) is embedded in the element isolation section 13 having the STI structure. Meanwhile, in the imaging element 1A of the present modification example, the element isolation section 13 having the STI structure and the element isolation section 14 having the FTI structure are each embedded with a portion (for example, the embedded part 24X or 24Y) of the gate electrode, the embedded part 24X embedded in the element isolation section 13 is embedded deeper than the embedded part 24Y embedded in the element isolation section 14. Except for this point, the imaging element 1A has a substantially similar configuration to the imaging element 1 according to the above-described first embodiment.

In this way, in the imaging element 1A of the present modification example, a portion of the gate electrode of the plurality of pixel transistor is embedded in each of the element isolation section 13 having the STI structure and the element isolation section 14 having the FTI structure, and is embedded deeper in the pixel element isolation section 13 than the pixel separation section 14. Thus, also in a case where a portion of the gate electrode is embedded in both of the element isolation section 13 and the element isolation section 14, as in the above-described first embodiment, it becomes possible to form the channel region 11X between the element isolation section 13 and the element isolation section 14 with a substantially uniform depth. Therefore, the characteristic variation of the pixel transistors is improved, and the RTS noise is reduced, and thus it is possible to improve the image quality.

### 3. Modification Example 2

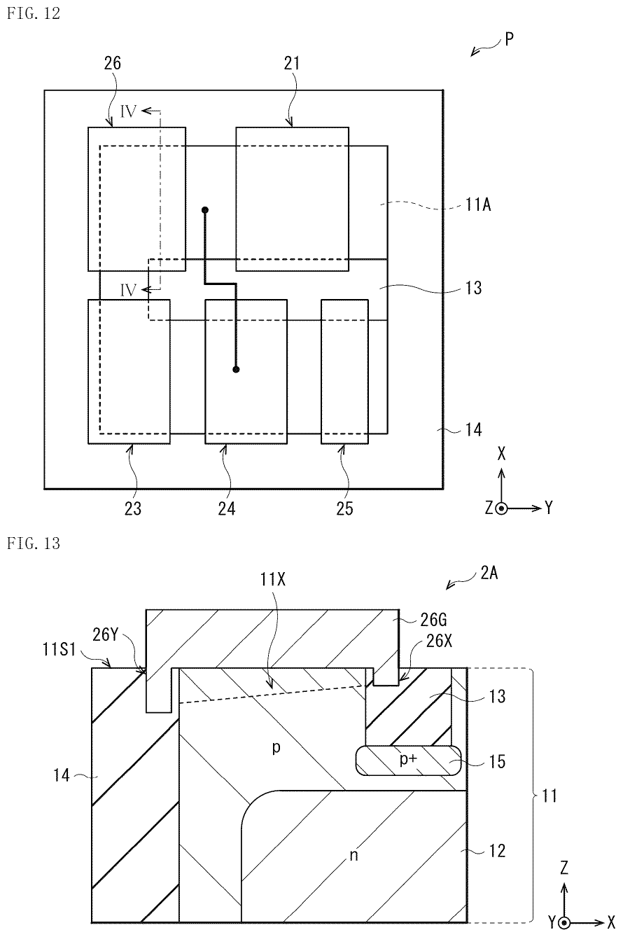

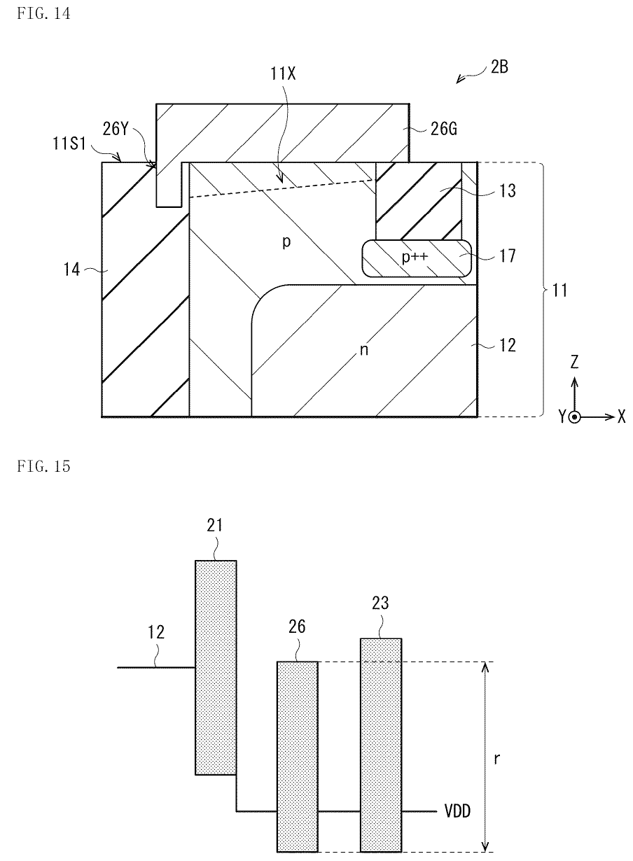

FIG. 7 schematically illustrates a cross-sectional configuration of a main part of an imaging element (an imaging element 1B) according to modification example 1 of the present disclosure. FIG. 8 schematically illustrates a planar configuration of the imaging element 1B illustrated in FIG. 7, and FIG. 7 illustrates a cross-section along a line II-II illustrated in FIG. 8. For example, as in the above-described first embodiment, the imaging element 1B constitutes one pixel (a unit pixel P) in the imaging device 100 such as a CMOS image sensor used in an electronic apparatus such as a digital still camera or a video camera.

In the above-described first embodiment, a portion (the embedded part 24X) of the gate electrode of the multiple pixel transistors (for example, the gate electrode 24G of the AMP 24) is embedded in the element isolation section 13 having the STI structure. Meanwhile, in the imaging element 1B of the present modification example, below the gate electrode of the pixel transistor (for example, the gate electrode 24G of the AMP 24) nearer the solation section 14 having the FTI structure, a p-type diffusion layer (p++) 16 having a higher impurity concentration than the p-type diffusion layer (p+) 15 formed in the lower part of the element isolation section 13 is provided, for example, at substantially the same height as the p-type diffusion layer (p+) 15.

In the entire unit pixel P, the p-type diffusion layer (p++) 16 is provided along a side surface of the solation section 14 extending in a direction (the Y-axis direction) in which the RST 23, the AMP 24, and the SEL 25 and the TRG 21 and the FDG 26 are provided in parallel. This p-type diffusion layer (p++) 16 corresponds to a specific example of a “second impurity diffusion layer” of the present disclosure. Except for this point, the imaging element 1B has a substantially similar configuration to the imaging element 1 according to the above-described first embodiment.

In this way, in the imaging element 1B of the present modification example, below the gate electrode of the pixel transistor nearer the solation section 14 having the FTI structure, the p-type diffusion layer (p++) 16 having a higher impurity concentration than the p-type diffusion layer (p+) 15 formed in the lower part of the element isolation section 13 is provided. Thus, even in a case where embedding a portion of the gate electrode of the pixel transistor as in the imaging element 1 of the above-described first embodiment is not enough to form the channel region 11X between the element isolation section 13 and the element isolation section 14 with a substantially uniform depth, it becomes possible to form the substantially-uniform channel region 11X between the element isolation section 13 and the element isolation section 14.

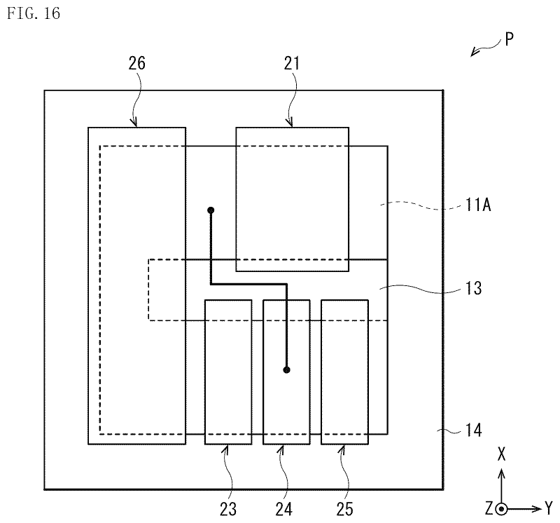

FIG. 9 illustrates a cross-section of the imaging element 1B along a line III-III illustrated in FIG. 8. Furthermore, in a case where the p-type diffusion layer (p++) 16 is provided nearer the element isolation section 14 below the gate electrode of the pixel transistor that does not cause a larger amount of current to flow than the AMP 24 does like the RST 23 and the FDG 26, the channel region 11X is formed deeper on the side of the element isolation section 14. Thus, it is possible to control the potential under the gate electrode of the pixel transistor and control the amount of electric charge held in the FD 22.

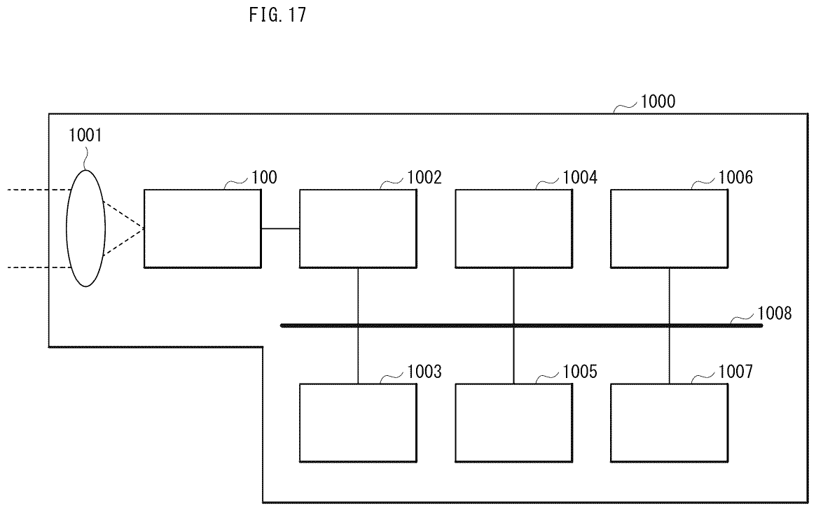

For example, as illustrated in FIG. 9, a portion (an embedded part 26X) of a gate electrode 26G of the FDG 26 is embedded in the element isolation section 13, and furthermore, the p-type diffusion layer (p++) 16 having a higher impurity concentration than the p-type diffusion layer (p+) 15 is provided below the gate electrode 26G of the FDG 26, thereby it is possible to expand a potential range (r) of when the FDG 26 is turned on/off, for example, as illustrated in FIG. 10. Thus, it is possible to improve a pixel characteristic.

Furthermore, by embedding the embedded part 26X deeper in the element isolation section 13, the channel region 11X is formed at a corner of the element isolation section 13 and the gate electrode 26G. Thus, it becomes possible to control the on/off of the FDG 26 at the corner. That is, it is possible to expand the potential range (r) by controlling the level of a potential of Si under the gate when the gate electrode 26G of the FDG 26 is closed and the level of a potential of Si under the gate when the gate electrode 26G is open. Therefore, it is possible to increase the amount of electric charge held in the FD 22 and improve the degree of freedom in the potential design. Furthermore, it is possible to make the channel length (W) shorter, and therefore, the degree of freedom in the layout is improved.

### 4. Second Embodiment

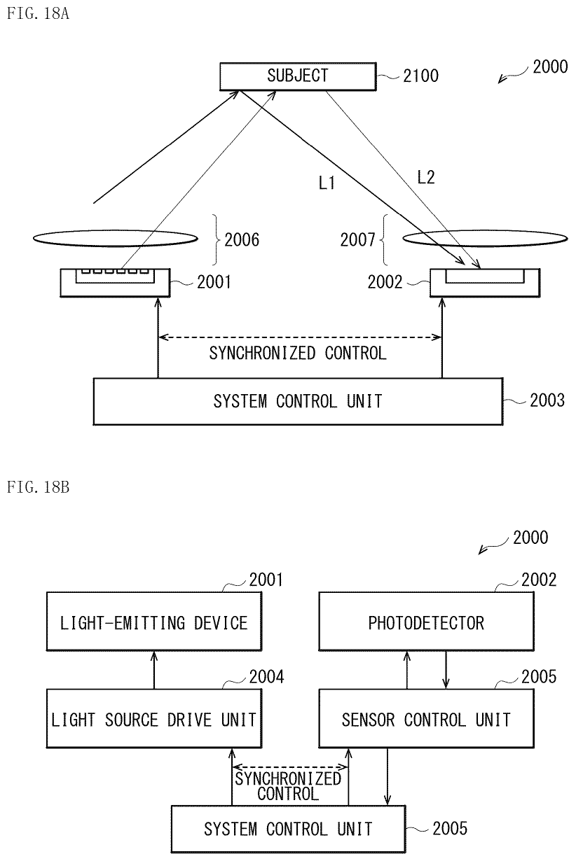

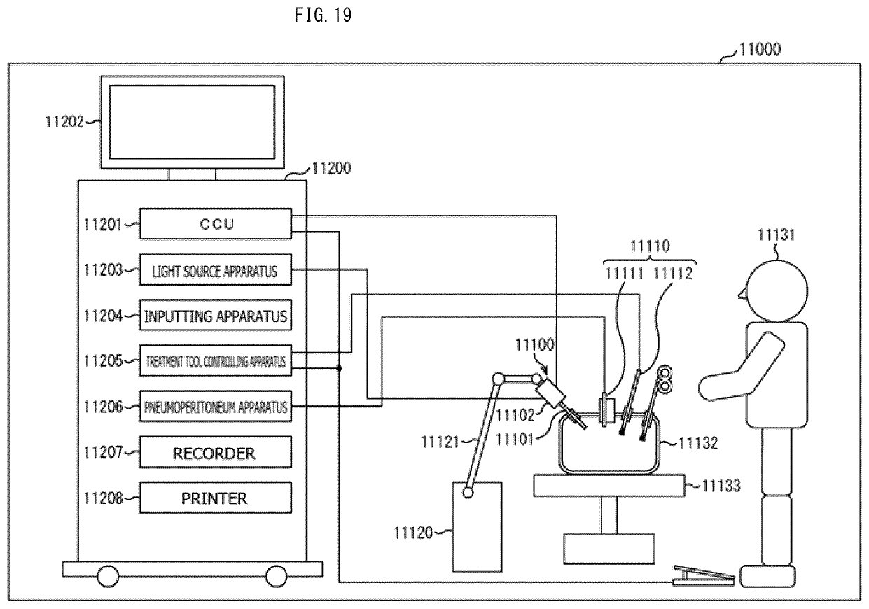

FIG. 11 schematically illustrates a cross-sectional configuration of a main part of an imaging element (an imaging element 2) according to the second embodiment of the present disclosure. FIG. 12 schematically illustrates a planar configuration of the imaging element 2 illustrated in FIG. 11, and FIG. 11 illustrates a cross-section along a line IV-IV illustrated in FIG. 12. For example, as in the above-described first embodiment, the imaging element 2 constitutes one pixel (a unit pixel P) in the imaging device 100 such as a CMOS image sensor used in an electronic apparatus such as a digital still camera or a video camera.

In the above-described first embodiment, a portion (the embedded part 24X) of the gate electrode (for example, the gate electrode 24G of the AMP 24) of the multiple pixel transistors is embedded in the element isolation section 13 having the STI structure. Meanwhile, in the imaging element 2 of the present embodiment, in the pixel transistor that the active region 11A under the gate electrode has an L-shape, a portion (an embedded part 26Y) of a gate electrode (for example, the gate electrode 26G of the FDG 26) is embedded in the element isolation section 14 having the FTI structure. Except for this point, the imaging element 2 has a substantially similar configuration to the imaging element 1 according to the above-described first embodiment.

In the pixel transistor that the active region 11A under the gate electrode has an L-shape as illustrated in FIG. 12, the channel length is shorter in the inside of the L-shape, and a characteristic of the FDG 26 is degraded by a short channel effect, and the characteristic variation of the pixel transistors increases.

Meanwhile, in the imaging element 2 of the present embodiment, a portion of the gate electrode of the pixel transistor that the active region 11A under the gate electrode has an L-shape (for example, the embedded part 26Y of the gate electrode 26G of the FDG 26) is embedded in the element isolation section 14. Thus, the channel region 11X is formed deep on the side of the element isolation section 14 as illustrated in FIG. 11, thus the short channel effect is reduced. Therefore, it becomes possible to reduce the degradation of the characteristic of the pixel transistor and reduce the characteristic variation of the pixel transistors.

### 5. Modification Example 3

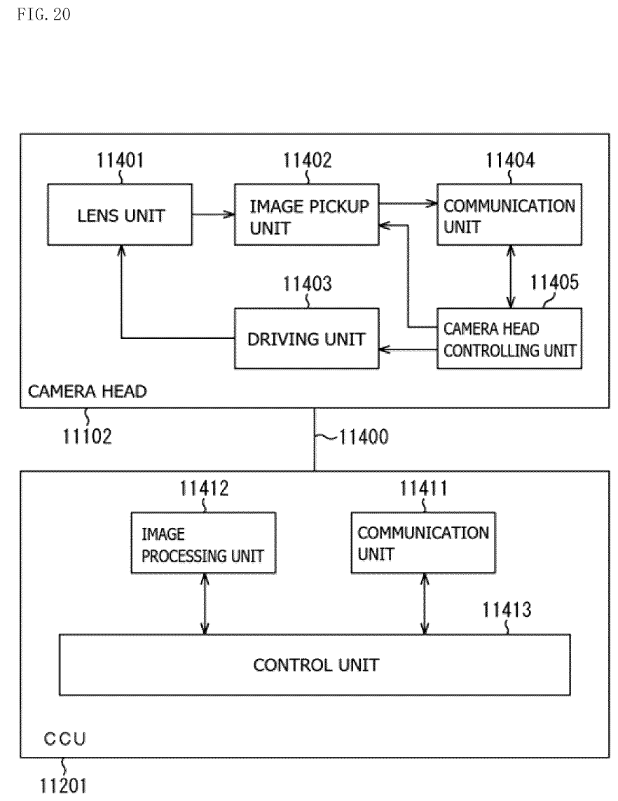

FIG. 13 schematically illustrates a cross-sectional configuration of a main part of an imaging element (an imaging element 2A) according to modification example 3 of the present disclosure. For example, as in the above-described first embodiment, the imaging element 2A constitutes one pixel (a unit pixel P) in the imaging device 100 such as a CMOS image sensor used in an electronic apparatus such as a digital still camera or a video camera.

In the above-described second embodiment, a portion (the embedded part 26Y) of the gate electrode of the pixel transistor that the active region 11A under the gate electrode has an L-shape (for example, the gate electrode 26G of the FDG 26) is embedded in the element isolation section 14 having the FTI structure. Meanwhile, in the imaging element 2A of the present modification example, the element isolation section 13 having the STI structure and the element isolation section 14 having the FTI structure are each embedded with a portion (for example, the embedded part 26X or 26Y) of the gate electrode, and the embedded part 26Y embedded in the element isolation section 14 is embedded deeper than the embedded part 24X embedded in the element isolation section 13. Except for this point, the imaging element 2A has a substantially similar configuration to the imaging element 2 according to the above-described second embodiment.

In this way, in the imaging element 2A of the present modification example, the element isolation section 13 having the STI structure and the element isolation section 14 having the FTI structure are each embedded with a portion of the gate electrode, and the portion is embedded deeper in the element isolation section 14 than that is in the element isolation section 13. Thus, also in a case where a portion of the gate electrode is embedded in both of the element isolation section 13 and the element isolation section 14, as in the above-described second embodiment, the channel region 11X is formed deep on the side of the element isolation section 14, thus the short channel effect is reduced. Therefore, it becomes possible to reduce the degradation of the characteristic of the pixel transistor and reduce the characteristic variation of the pixel transistors.

### 6. Modification Example 4

FIG. 14 schematically illustrates a cross-sectional configuration of a main part of an imaging element (an imaging element 2B) according to modification example 4 of the present disclosure. For example, as in the above-described first embodiment, the imaging element 2B constitutes one pixel (a unit pixel P) in the imaging device 100 such as a CMOS image sensor used in an electronic apparatus such as a digital still camera or a video camera.

In the above-described second embodiment, a portion (the embedded part 26Y) of the gate electrode of the pixel transistor that the active region 11A has an L-shape (for example, the gate electrode 26G of the FDG 26) is embedded in the element isolation section 14 having the FTI structure. Meanwhile, in the imaging element 2B of the present modification example, a p-type diffusion layer (p++) 17 having a higher impurity concentration than the p-type diffusion layer (p+) 15 of the above-described first embodiment is provided in the lower part of the element isolation section 13. Except for this point, the imaging element 2B has a substantially similar configuration to the imaging element 2 according to the above-described second embodiment.

In this way, in the imaging element 2B of the present modification example, the p-type diffusion layer (p++) 17 having a higher impurity concentration than the p-well is provided in the lower part of the element isolation section 13, thus the short channel effect is further reduced. Therefore, it becomes possible to further reduce the degradation of the characteristic of the pixel transistor and further reduce the characteristic variation of the pixel transistors.

Furthermore, in the pixel transistor that the active region 11A under the gate electrode has an L-shape and does not cause a larger amount of current to flow than the AMP 24 does like the RST 23 and the FDG 26, as in the present modification example, the p-type diffusion layer (p++) 17 having a high impurity concentration is provided in the lower part of the element isolation section 13, thereby it is possible to control the potential under the gate electrode of each pixel transistor and control the amount of electric charge held in the FD 22. By providing the p-type diffusion layer (p++) 17 having a higher impurity concentration than the p-well in the lower part of the element isolation section 13, for example, as illustrated in FIG. 14, it becomes possible to expand, for example, the potential range (r) of when the FDG 26 is turned on/off, for example, as illustrated in FIG. 15, and therefore, it becomes possible to improve the pixel characteristic.

Moreover, the channel region 11X is formed at the corner of the element isolation section 14 and the gate electrode 26G, thus it becomes possible to control the on/off of the FDG 26 at the corner, and is possible to expand a voltage range of CutL/H. Therefore, it is possible to increase the amount of electric charge held in the FD 22 and improve the degree of freedom in the potential design. Furthermore, it is possible to make the channel length (W) shorter, and therefore, the degree of freedom in the layout is improved.

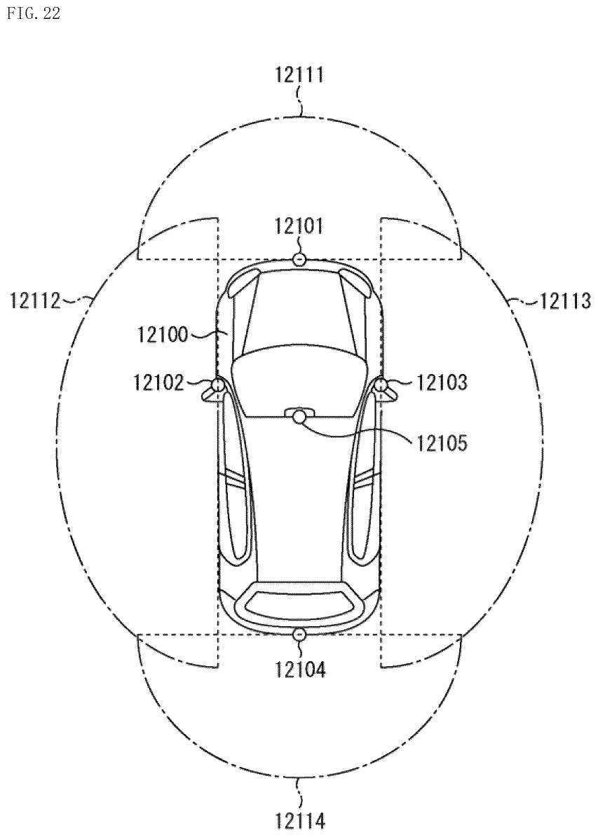

It is to be noted that the active region 11A of the pixel transistor is not limited to have an L-shape, and may have, for example, a U-shape as illustrated in FIG. 16. Also in that case, by embedding a portion of the gate electrode in, of the element isolation section 13 having the STI structure and the element isolation section 14 having the FTI structure, only the element isolation section 14 side or both of the element isolation sections 13 and 14 to cause it to be embedded deeper in the element isolation section 14, it becomes possible to obtain similar effects to those of the above-described second embodiment and modification example 3. Furthermore, by providing the p-type diffusion layer (p++) 17 in the lower part of the element isolation section 13, it becomes possible to obtain similar effects to those of the above-described modification example 4.

### 7. Application Examples

### (Application Example 1)

For example, the imaging element 1 and the imaging device 100 including the imaging element 1 that have been described above are applicable to various electronic apparatuses, for example, an imaging system such as a digital still camera or a digital video camera, a cell phone having an imaging function, and other devices having an imaging function.

FIG. 17 is a block diagram illustrating an example of a configuration of an electronic apparatus 1000.

As illustrated in FIG. 17, the electronic apparatus 1000 includes an optical system 1001, the imaging device 100, and a digital signal processor (DSP) 1002, and has a configuration in which the DSP 1002, a memory 1003, a display device 1004, a recording device 1005, an operation system 1006, and a power supply system 1007 are coupled through a bus 1008, and is able to take a still image and a moving image.

The optical system 1001 includes one or more lenses, and takes in incident light (image light) from a subject and forms an image on the imaging plane of the imaging device 100.

The imaging device 100 converts an amount of the incident light formed as an image on the imaging plane by the optical system 1001 into an electrical signal on a pixel-by-pixel basis, and supplies the electrical signal as a pixel signal to the DSP 1002.

The DSP 1002 performs various signal processing on the signal from the imaging device 100 and obtains an image, and temporarily stores data of the image in the memory 1003. The data of the image stored in the memory 1003 is recorded on the recording device 1005, or is supplied to the display device 1004 to display the image. Furthermore, the operation system 1006 receives various operations made by a user, and supplies an operation signal to each block of the electronic apparatus 1000, and the power supply system 1007 supplies electric power required to drive each block of the electronic apparatus 1000.

### (Application Example 2)

FIG. 18A schematically illustrates an example of an entire configuration of a light detection system 2000 including an imaging device (for example, the imaging device 100). FIG. 18B illustrates an example of a circuit configuration of the light detection system 2000. The light detection system 2000 includes a light-emitting device 2001 as a light source unit that emits infrared light L2 and a photodetector 2002 as a light receiving unit. For example, the above-described imaging device 100 is able to be used as the photodetector 2002. The light detection system 2000 may further include a system control unit 2003, a light source drive unit 2004, a sensor control unit 2005, a light-source-side optical system 2006, and a camera-side optical system 2007.

The photodetector 2002 is able to detect light L1 and light L2. The light L1 is light that ambient light from the outside has been reflected from a subject (an object to be measured) 2100 (FIG. 18A). The light L2 is light that that has been emitted from the light-emitting device 2001 and then reflected from the subject 2100. The light L1 is, for example, visible light, and the light L2 is, for example, infrared light. The light L1 is able to be detected in a photoelectric converter of the photodetector 2002, and the light L2 is able to be detected in a photoelectric conversion region of the photodetector 2002. It is possible to acquire image information of the subject 2100 from the light L1 and acquire information regarding the distance between the subject 2100 and the light detection system 2000 from the light L2. The light detection system 2000 is able to be installed, for example, in an electronic apparatus such as a smartphone or a moving body such as a vehicle. The light-emitting device 2001 may include, for example, a semiconductor laser, a surface-emitting semiconductor laser, or a vertical-cavity surface-emitting laser (VCSEL). As a method for the photodetector 2002 to detect the light L2 emitted from the light-emitting device 2001, for example, the iTOF method is able to be adopted; however, it is not limited to this. In the iTOF method, the photoelectric converter is able to measure the distance from the subject 2100 on the basis of, for example, time-of-flight (TOF) of light. As a method for the photodetector 2002 to detect the light L2 emitted from the light-emitting device 2001, for example, the structured light method and the stereovision method are also able to be adopted. For example, in the structured light method, light of a predetermined pattern is projected onto the subject 2100, and the distance between the light detection system 2000 and the subject 2100 is able to be measured by analyzing a state of distortion of the pattern. Furthermore, in the stereovision method, two or more images of the subject 2100 viewed from two or more different viewpoints are acquired with, for example, two or more cameras, thereby the distance between the light detection system 2000 and the subject is able to be measured. It is to be noted that the light-emitting device 2001 and the photodetector 2002 are able to be synchronously controlled by the system control unit 2003.

### 8. Practical Application Examples

### (Example of Practical Application to Endoscopic Surgery System)

The technique according to the present disclosure (the present technology) is applicable to various products. For example, the technique according to the present disclosure may be applied to an endoscopic surgery system.

FIG. 19 is a view depicting an example of a schematic configuration of an endoscopic surgery system to which the technology according to an embodiment of the present disclosure (present technology) can be applied.

In FIG. 19, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 20 is a block diagram depicting an example of a functional configuration of the camera head 11102 and the CCU 11201 depicted in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there has been described an example of the endoscopic surgery system to which the technique according to the present disclosure may be applied. The technique according to the present disclosure may be applied to, of the above-described components, the image pickup unit 11402. By applying the technique according to the present disclosure to the image pickup unit 11402, the detection accuracy is improved.

It is to be noted that, here, the endoscopic surgery system has been described as an example; however, the technique according to the present disclosure may be applied to other systems, for example, a micrographic surgery system or the like.

### (Example of Practical Application to Moving Body)

The technique according to the present disclosure is applicable to various products. For example, the technique according to the present disclosure may be realized as a device mounted on any of kinds of moving bodies such as a motor vehicle, an electric vehicle, a hybrid electric vehicle, a motorcycle, a bicycle, a personal transporter, an airplane, a drone, a vessel, a robot, construction equipment, and agricultural machinery (a tractor).

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there has been described an example of the moving body control system to which the technique according to the present disclosure may be applied. The technique according to the present disclosure may be applied to, of the above-described components, for example, the imaging section 12031. Specifically, the imaging elements (for example, the imaging element 1A) according to the above-described embodiments and their modification examples are applicable to the imaging section 12031. By applying the technique according to the present disclosure to the imaging section 12031, it becomes possible to obtain a high-definition taken image with less noise; therefore, it is possible to perform high-precision control using the taken image in the moving body control system.

The present technology has been described above with the first and second embodiments, modification examples 1 to 4, and the application examples and the practical application examples; however, the contents of the present disclosure are not limited to the above-described embodiments, etc., and it is possible to make various modifications. For example, between the n-type semiconductor region (n) constituting the photoelectric converter 12 and the element isolation section 14, a p-type diffusion region (p+) having a higher p-type impurity concentration may be formed.

Furthermore, in the above-described embodiments, etc., there has been provided an example of a configuration of a back-illuminated imaging element; however, the contents of the present disclosure are also applicable to a front-illuminated imaging element.

Moreover, the imaging device 100 and the electronic apparatus 1000 of the present disclosure do not have to include all the components described in the above-described embodiments, etc., and, instead, may include another component. For example, the electronic apparatus 1000 may be provided with a shutter for controlling the entrance of light to the imaging device 100, and may include an optical cut-off filter in accordance with the purpose of the electronic apparatus 1000.

It is to be noted that the effects described in the present specification are merely an example, and the effects of the present disclosure are not limited to those, and the present disclosure may have other effects.

It is to be noted that the present technology may have the following configuration. According to the present technology having the following configuration, a first element isolation section and a second element isolation section; the first and second element isolation sections having different depths from each other that define an active region of one or more pixel transistors are provided in a semiconductor substrate, and at least one of the first element isolation section or the second element isolation section is embedded with a portion of a gate electrode of the one or more pixel transistors with a different depth, thereby the shape of a channel region formed below the gate electrode is controlled. Therefore, it becomes possible to improve the image quality.

(1)

An imaging element including:
a semiconductor substrate including a photoelectric converter for each pixel;
one or more pixel transistors provided in one surface of the semiconductor substrate; and
a first element isolation section and a second element isolation section having different depths from each other that are embedded in the one surface of the semiconductor substrate and define an active region of the one or more pixel transistors,
in which a portion of a gate electrode of the one or more pixel transistors is embedded in at least one of the first and second element isolation sections at different depths.
   (2)

The imaging element according to (1), in which the depth of the first element isolation section is shallower than the depth of the second element isolation section.

(3)

The imaging element according to (1) or (2), in which the gate electrode has a first embedded part embedded in the first element isolation section.

(4)

The imaging element according to any one of (1) to (3), in which the gate electrode has the first embedded part embedded in the first element isolation section and a second embedded part embedded in the second element isolation section, and a depth of the first embedded part is deeper than a depth of the second embedded part.

(5)

The imaging element according to any one of (1) to (4), in which an impurity concentration below the gate electrode is higher on a side of the second element isolation section than on a side of the first element isolation section.

(6)

The imaging element according to (5), in which the semiconductor substrate further includes a first impurity diffusion layer and a second impurity diffusion layer, the first impurity diffusion layer being provided in a lower part of the first element isolation section and having a higher impurity concentration than a well region of the semiconductor substrate, and the second impurity diffusion layer being provided nearer the second element isolation section and having a higher impurity concentration than the first impurity diffusion layer.

(7)

The imaging element according to any one of (1) to (6), in which a channel region formed in the active region below the gate electrode is formed between the first element isolation section and the second element isolation section with substantially the same depth.

(8)

The imaging element according to (6) or (7), in which the channel region formed in the active region below the gate electrode is formed deeper on the side of the first element isolation section.

(9)

The imaging element according to any one of (1) to (8), in which the active region has an L-shape or a U-shape.

(10)

The imaging element according to (9), in which the gate electrode has the second embedded part embedded in the second element isolation section.

(11)

The imaging element according to (9) or (10), in which
the gate electrode has the first embedded part embedded in the first element isolation section and the second embedded part embedded in the second element isolation section, and
a depth of the second embedded part is deeper than a depth of the first embedded part.
   (12)

The imaging element according to any one of (9) to (11), in which an impurity concentration below the gate electrode is higher on the side of the first element isolation section than on the side of the second element isolation section.

(13)

The imaging element according to any one of (9) to (12), in which the channel region formed in the active region below the gate electrode is formed deeper on the side of the second element isolation section.

(14)

An electronic apparatus including an imaging element,
the imaging element including:
   a semiconductor substrate including a photoelectric converter for each pixel;
   one or more pixel transistors provided in one surface of the semiconductor substrate; and
   a first element isolation section and a second element isolation section having different depths from each other that are embedded in the one surface of the semiconductor substrate and define an active region of the one or more pixel transistors,
in which a portion of a gate electrode of the one or more pixel transistors is embedded in at least one of the first and second element isolation sections at different depths.

The present application claims the benefit of Japanese Priority Patent Application JP2022-147341 filed with the Japan Patent Office on Sep. 15, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. An imaging element, comprising:
a semiconductor substrate including a photoelectric converter for each pixel;
one or more pixel transistors provided in one surface of the semiconductor substrate; and
a first element isolation section and a second element isolation section having different depths from each other that are embedded in the one surface of the semiconductor substrate and define an active region of the one or more pixel transistors, wherein a portion of a gate electrode of the one or more pixel transistors is embedded in at least one of the first and second element isolation sections at different depths.

2. The imaging element according to claim 1, wherein the depth of the first element isolation section is shallower than the depth of the second element isolation section.

3. The imaging element according to claim 1, wherein the gate electrode has a first embedded part embedded in the first element isolation section.

4. The imaging element according to claim 1, wherein
the gate electrode has a first embedded part embedded in the first element isolation section and a second embedded part embedded in the second element isolation section, and
a depth of the first embedded part is deeper than a depth of the second embedded part.

5. The imaging element according to claim 1, wherein an impurity concentration below the gate electrode is higher on a side of the second element isolation section than on a side of the first element isolation section.

6. The imaging element according to claim 5, wherein the semiconductor substrate further includes a first impurity diffusion layer and a second impurity diffusion layer, the first impurity diffusion layer being provided in a lower part of the first element isolation section and having a higher impurity concentration than a well region of the semiconductor substrate, and the second impurity diffusion layer being provided nearer the second element isolation section and having a higher impurity concentration than the first impurity diffusion layer.

7. The imaging element according to claim 1, wherein a channel region formed in the active region below the gate electrode is formed between the first element isolation section and the second element isolation section with a substantially same depth.

8. The imaging element according to claim 6, wherein a channel region formed in the active region below the gate electrode is formed deeper on a side of the first element isolation section.

9. The imaging element according to claim 1, wherein the active region has an L-shape or a U-shape.

10. The imaging element according to claim 9, wherein the gate electrode has a second embedded part embedded in the second element isolation section.

11. The imaging element according to claim 9, wherein
the gate electrode has a first embedded part embedded in the first element isolation section and a second embedded part embedded in the second element isolation section, and
a depth of the second embedded part is deeper than a depth of the first embedded part.

12. The imaging element according to claim 9, wherein an impurity concentration below the gate electrode is higher on a side of the first element isolation section than on a side of the second element isolation section.

13. The imaging element according to claim 9, wherein a channel region formed in the active region below the gate electrode is formed deeper on a side of the second element isolation section.

14. An electronic apparatus comprising an imaging element,
the imaging element including:
a semiconductor substrate including a photoelectric converter for each pixel;
one or more pixel transistors provided in one surface of the semiconductor substrate; and
a first element isolation section and a second element isolation section having different depths from each other that are embedded in the one surface of the semiconductor substrate and define an active region of the one or more pixel transistors,
wherein a portion of a gate electrode of the one or more pixel transistors is embedded in at least one of the first and second element isolation sections at different depths.
